(19) United States
(12) Patent Application Publication
(10) Pub. No.: US 2013/0037867 A1
(43) Pub. Date: Feb. 14, 2013

(54) SEMICONDUCTOR DEVICE AND MANUFACTURING METHOD THEREOF

(71) Applicant: Kanna ADACHI, Chigasaki-shi (JP)

(72) Inventor: Kanna ADACHI, Chigasaki-shi (JP)

(73) Assignee: Kabushiki Kaisha Toshiba, Minato-Ku (JP)

(21) Appl. No.: 13/403,302

(22) Filed: Feb. 23, 2012

(30) Foreign Application Priority Data
Aug. 12, 2011 (JP) 2011-176947

(51) Int. Cl. H01L 29/772; H01L 21/336

(52) U.S. Cl. 257/288; 438/303; 257/E29.242; 257/E21.409

(57) ABSTRACT

According to one embodiment, a semiconductor device includes a substrate, a gate electrode, a channel region, a source region and a drain region. The source region forms a first boundary with the channel region, and the drain region forms a second boundary with the channel region. A side of the gate electrode at the side of the source region has a plurality of convex portions extending along a gate length direction, a side of the gate electrode at the side of the drain region is parallel to a gate width direction, the first boundary and the second boundary have shapes corresponding to the side of the gate electrode at the side of the source region and the side of the gate electrode at the side of the drain region, and the length of the first boundary is more than the length of the second boundary.

### CROSS-REFERENCE TO RELATED APPLICATION

This application is based upon and claims the benefit of priority from prior Japanese Patent Application No. 2011-176947 filed on Aug. 12, 2011, the entire contents of which are incorporated herein by reference.

### FIELD

Embodiments of the present invention relate to a semiconductor device and a manufacturing method thereof.

### BACKGROUND

In order to improve performance of a logic-type semiconductor integrated circuit such as a microprocessor or an application specific integrated circuit (ASIC) or increase the capacity of a memory-type semiconductor integrated circuit, minuteness to decrease a size of semiconductor elements constituting the integrated circuit is advanced.

For example, in a metal insulator semiconductor field effect transistor (MISFET) that is one of the semiconductor elements, it becomes difficult to suppress a short-channel effect due to advancement of the minuteness and it becomes difficult to decrease a power-supply voltage or decrease a current of a subthreshold region. As a result, it becomes difficult to decrease consumption power of the MISFET.

For this reason, it is studied to apply a tunnel FET using tunneling between bands of semiconductors to a logic circuit or a static random access memory (SRAM), instead of the conventional MISFET.

A structure of the tunnel FET is mainly divided into two structures of a structure where tunneling between bands is generated in a transverse direction and a structure where tunneling between bands is generated in a longitudinal direction.

### BRIEF DESCRIPTION OF THE DRAWINGS

FIGS. 1 (a) and 1 (b) are a plan view and a cross-sectional view of a semiconductor device according to an embodiment;

FIGS. 2 to 7 are plan views and cross-sectional views illustrating processes for manufacturing the semiconductor device according to the embodiment;

FIGS. 8 (a) and 8 (b) are a plan view and a cross-sectional view of a semiconductor device according to a first modification; and

FIGS. 9 (a) and 9 (b) are a plan view and a cross-sectional view of a semiconductor device according to a second modification.

### DETAILED DESCRIPTION

In one embodiment, a semiconductor device includes a substrate, a gate electrode provided on the substrate via a gate insulating film, a channel region provided on the substrate below the gate electrode, a source region provided on the substrate to be adjacent to one side of the channel region, the source region having first impurities and forming a first boundary with the channel region, the first boundary being tunnel channel for carriers, and a drain region provided on the substrate to be adjacent to the other side of the channel region, the drain region having second impurities and forming a second boundary with the channel region. In the semiconductor device, a side of the gate electrode at the side of the source region has a plurality of convex portions extending along a gate length direction, a side of the gate electrode at the side of the drain region is parallel to a gate width direction, the first boundary and the second boundary have shapes corresponding to the side of the gate electrode at the side of the source region and the side of the gate electrode at the side of the drain region, and the length of the first boundary on a surface of the substrate is more than the length of the second boundary.

Hereafter, an embodiment will be described with reference to the drawings. However, the present invention is not limited to the embodiment. Like reference numbers refer to like elements in all of the drawings and the redundant description will not be repeated. In addition, the drawings are schematic views to promote explanation of the present invention and the understanding thereof, and the shapes, dimensions, and ratios thereof may be different from those of real devices. However, a design can be appropriately changed in consideration of the following explanation and a well-known technology.

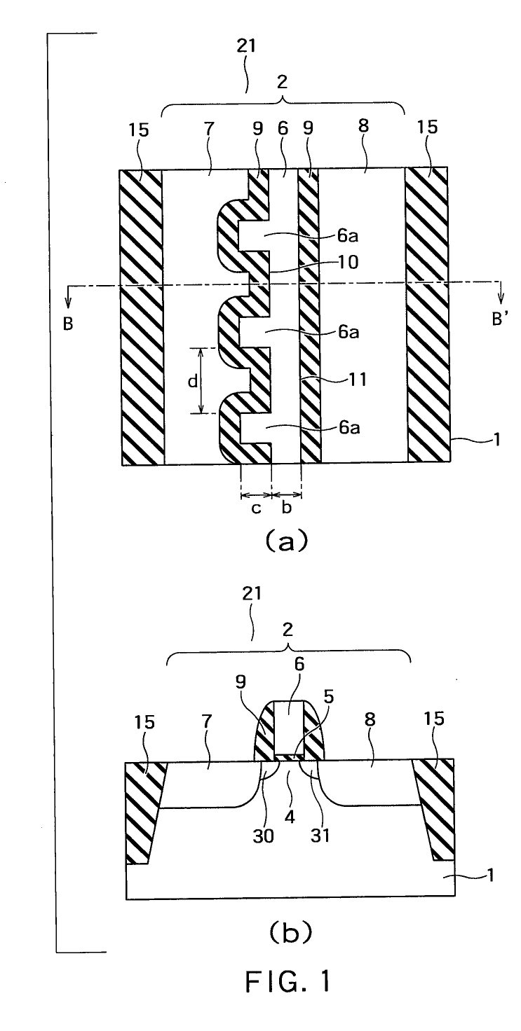

A tunnel FET (semiconductor device) 21 according to this embodiment will be described using FIGS. 1 (a) and 1 (b). The tunnel FET according to this embodiment has a structure in which a channel region and a source region contact in a transverse direction and tunneling between bands is generated in a transverse direction. In the tunnel FET 21, each of a source region 7 and a drain region 8 is configured using a diffusion layer of a different type. In this case, an n-type tunnel FET where the source region 7 is configured using a p-type diffusion layer and the drain region 8 is configured using an n-type diffusion layer is described. However, the present invention is not limited thereto and the tunnel FET 21 may be a p-type tunnel FET.

FIG. 1 (a) illustrates a plane of the tunnel FET 21 and FIG. 1 (b) illustrates a cross-section of the tunnel FET 21 along a gate length direction, that is, a cross-section taken along the line B-B′ of FIG. 1 (a).

In the description below, the gate length direction means a direction along the length of an interval between the source region 7 and the drain region 8, and a gate width direction means a direction crossing the gate length direction.

As illustrated in FIG. 1 (a), in the tunnel FET 21 according to this embodiment, a pair of shallow trench isolations (STI) 15 for element isolation are formed in a semiconductor substrate 1 and a region between the pair of STIs 15 is an element region 2. In FIG. 1 (a), a left portion of the element region 2 is the p-type source region 7 and a right portion thereof is the n-type drain region 8. Between the source region 7 and the drain region 8, a gate electrode 6 is formed on the semiconductor substrate 1 via a gate insulating film 5.

A side of the gate electrode 6 at the side of the source region 7 has convex portions 6a that extend along the gate length direction (in FIG. 1 (a), transverse direction) and a side of the gate electrode 6 at the side of the drain region 8 is parallel to the gate width direction (in FIG. 1 (a), vertical direction). In detail, as illustrated in FIG. 1 (a), the gate electrode 6 has a shape of a comb that has comb teeth at the side of the source region 7. In FIG. 1 (a), for example, the length of the gate electrode 6 along the gate length direction that is illustrated by “b” is 50 nm and the length of the convex portion 6a along the gate length direction that is illustrated by “c” is 50 nm. The shape of the gate electrode 6 is not limited to the shape of the comb in which the convex portion 6a has a rectangular shape and may be a shape of saw teeth in which the convex portion 6a has a triangular shape. The shape and the size of the convex portion 6a can be appropriately selected according to a characteristic or precision of a manufacturing process required with respect to the tunnel FET 21.

As will be described below, since the source region 7 and the drain region 8 are formed by implanting ions using the gate electrode 6 as a mask, the source region 7 and the drain region 8 have shapes that correspond to the shape of the gate electrode 6. Therefore, a first boundary 10 that is a boundary of the source region 7 and the channel region 4 has an uneven shape. In detail, in FIG. 1 (a), the first boundary 10 has a rectangular wave shape. A second boundary 11 that is a boundary of the drain region 8 and the channel region 4 becomes a straight line that is parallel to the gate width direction. Therefore, on a surface of the semiconductor substrate 1, the length of the first boundary 10 becomes more than the length of the second boundary 11. A shape of the first boundary 10 may be an uneven shape such that the length thereof becomes more than the length of the secondary boundary 11 and is not limited to a rectangular wave shape. In the tunnel FET 21, since carriers flow around the surface of the semiconductor substrate 1 below the gate electrode 6, places where the carriers perform tunneling between the bands are places that are positioned around the surface of the semiconductor substrate 1 and are positioned on the first boundary 10. Therefore, on the surface of the semiconductor substrate 1, by forming the first boundary 10 in the uneven shape and increasing the length of the first boundary 10 to be more than the second boundary 11, the channel width of the channel region 4 at the side of the source region 7 can be increased to be more than the channel width of the channel region 4 at the side of the drain region 8. As a result, the places where the carriers perform tunneling increase and a drain current of the tunnel FET 21 can be increased.

As illustrated in FIG. 1 (a), since the side of the gate electrode 6 at the side of the source region 7 has the convex portions 6a extending along the gate length direction, one tunneling FET 21 has the different gate length (distance between the source region 7 and the drain region 8) according to the position along the gate width direction. In detail, the gate length changes periodically along the gate width direction.

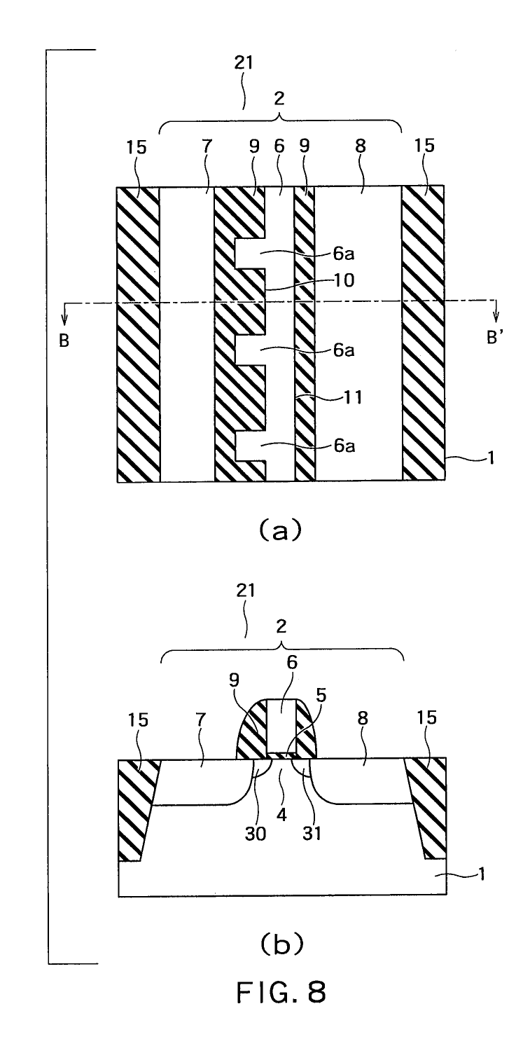

In addition, the side of the gate electrode 6 is covered with a sidewall film 9. As illustrated in FIG. 1 (a), the sidewall film 9 may be formed along the shape of the gate electrode 6 without burying regions between the adjacent convex portions 6a. Alternatively, as illustrated in FIGS. 8 (a) and 8 (b) (FIG. 8 (a) is a plan view of a semiconductor device according to a first modification and FIG. 8 (b) is a cross-sectional view thereof), the sidewall film 9 may be formed to bury the regions between the adjacent convex portions 6a. A shape of the sidewall film 9 may has a rectangular wave shape, a triangular wave shape, or a semicircular wave shape. However, the shape of the sidewall film 9 is not limited, and may be appropriately selected according to a characteristic required with respect to the tunnel FET 21. When the sidewall film 9 is formed not to bury the regions between the adjacent convex portions 6a, an interval “d” of the adjacent convex portions 6a illustrated in FIG. 1 (a) is preferably two times more than the thickness of the sidewall film 9.

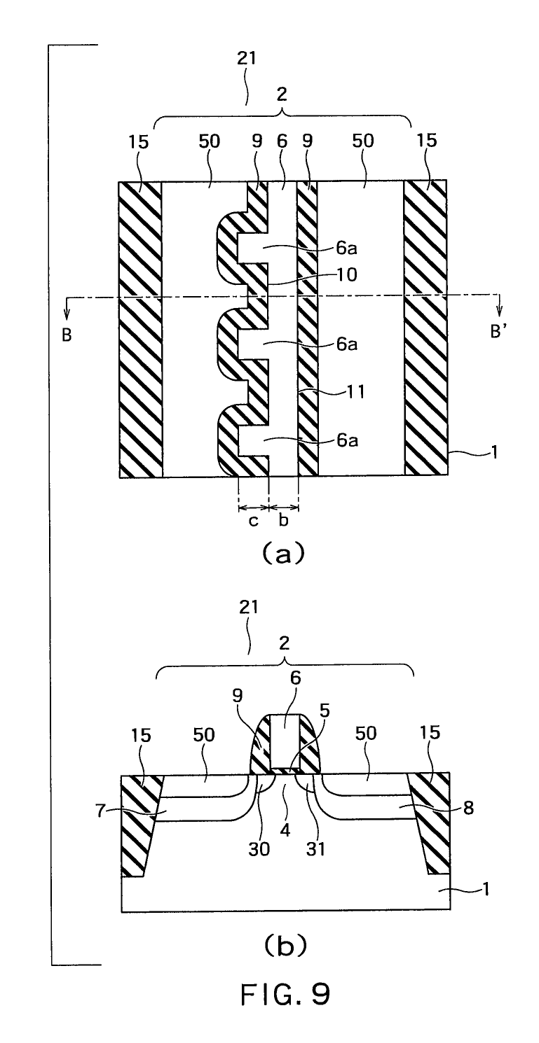

As illustrated in FIGS. 9 (a) and 9 (b) (FIG. 9 (a) is a plan view of a semiconductor device according to a second modification and FIG. 9 (b) is a cross-sectional view thereof), the surfaces of the source region 7 and the drain region 8 may be covered with a silicide film 50. At this time, when the sidewall film 9 is formed not to bury the regions between the adjacent convex portions 6a, the silicide film 50 may be formed between the adjacent convex portions 6a covered with the sidewall film 9 or the silicide film 50 may not be formed between the adjacent convex portions 6a. When the sidewall film 9 is formed to bury the regions between the adjacent convex portions 6a, the silicide film 50 is not formed between the adjacent convex portions 6a. The existence or non-existence and the shape of the silicide film 50 can be appropriately selected according to the characteristic required with respect to the tunnel FET 21.

Next, the cross-section of the tunnel FET 21 according to this embodiment will be described using FIG. 1 (b). The pair of STIs 15 for element isolation are formed on the silicon substrate 1 and the region between the pair of STIs 15 is the element region 2.

In a center portion of the element region 2, the gate electrode 6 that is provided on the semiconductor substrate 1 via the gate insulating film 5 and the sidewall film 9 that covers the sides of the gate insulating film 5 and the gate electrode 6 are provided. At the semiconductor substrate 1 below the gate electrode 6, the channel region 4 is positioned. The source region 7 and the drain region 8 are formed on the semiconductor substrate 1 to interpose the channel region 4 between the source region and the drain region along the gate length direction (in FIG. 1 (b), transverse direction). In detail, on the right side of the channel region 4, the source region 7 that has a source extension layer 30 formed to partially overlap an end of the gate electrode 6 at the side of the source region 7 is formed to be adjacent to one side of the channel region 4. On the left side of the channel region 4, the drain region 8 that has a drain extension layer 31 formed to partially overlap an end of the gate electrode 6 at the side of the drain region 8 is formed to be adjacent to the other side of the channel region 4.

The semiconductor substrate 1 is configured using a silicon substrate. However, the semiconductor substrate 1 is not limited to the silicon substrate and may be configured using other substrate such as a SiGe substrate.

The STI 15 is configured using a groove where an insulating film such as silicon oxide is buried.

The gate electrode 6 is configured using polycrystalline silicon, tungsten, or aluminum.

The gate insulating film 5 is configured using silicon oxide.

The sidewall film 9 is configured using a silicon oxide film or a silicon nitride film.

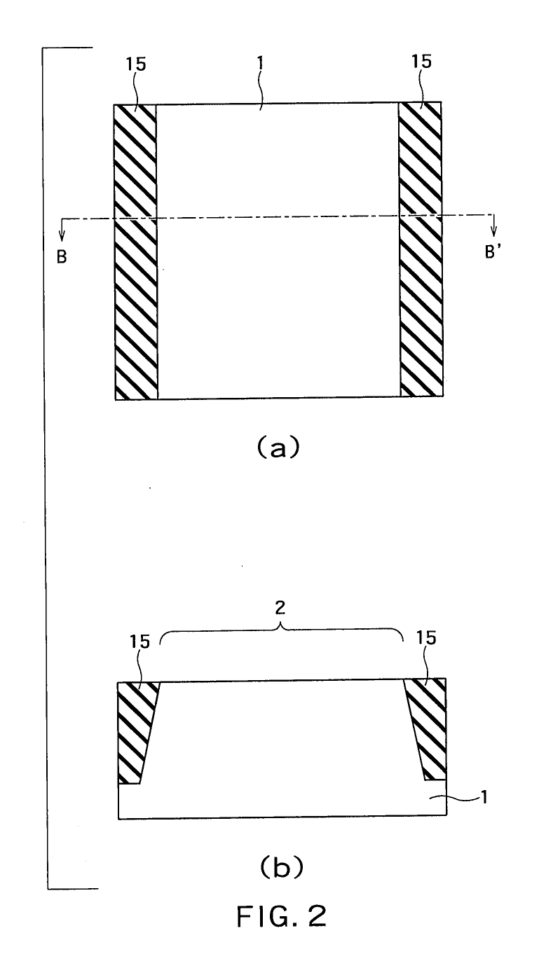

Next, a method of manufacturing the tunnel FET 21 according to this embodiment will be described using FIGS. 2 to 7. FIGS. 2 to 7 are diagrams illustrating processes of the method of manufacturing the tunnel FET 21 according to this embodiment. In detail, FIGS. 2 (a), 3 (a), 4 (a), 5 (a), 6 (a), and 7 (a) are plan views of the individual processes and FIGS. 2 (b), 3 (b), 4 (b), 5 (b), 6 (b), and 7 (b) illustrate cross-sections along the gate length direction of the plan views of FIGS. 2 (a), 3 (a), 4 (a), 5 (a), 6 (a), and 7(a) of the individual processes, in detail, cross-sections taken along the lines B-B′ of the plan views of FIGS. 2 (a), 3 (a), 4 (a), 5 (a), 6 (a), and 7 (a) of the individual processes.

First, as illustrated in FIGS. 2 (a) and 2 (b), the pair of STIs 115 are formed to interpose the element region 2 therebetween in order to electrically isolate the element region 2 of the semiconductor substrate 1. The center portion of the element region 2 becomes the channel region. However, the p-type or n-type impurities may be implanted into the channel region to obtain a desired threshold voltage of the tunnel FET 21.

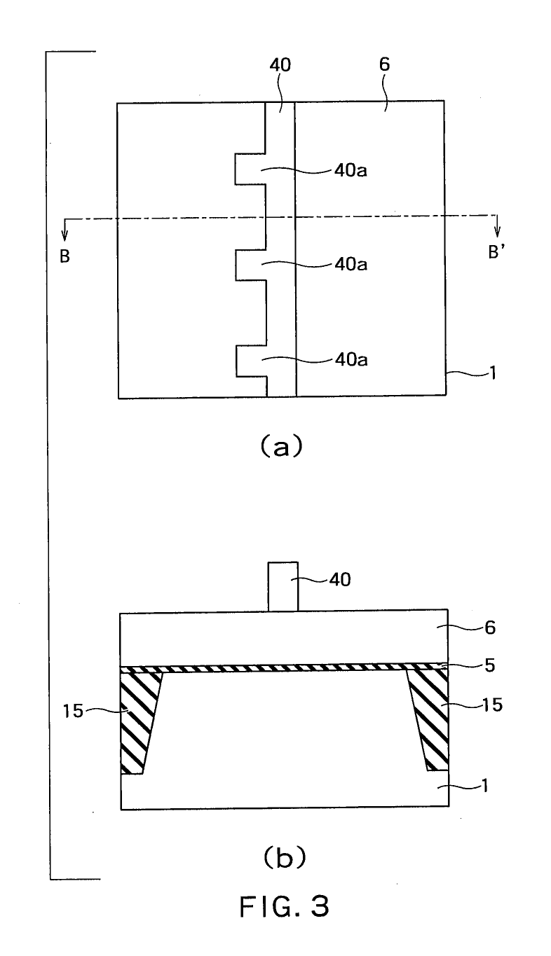

Next, as illustrated in FIGS. 3 (a) and 3 (b), the gate insulating film 5 and the gate electrode 6 formed on the gate insulating film 5 are deposited with the desired thicknesses, by using a chemical vapor deposition (CVD) method. A resist 40 is formed on the gate electrode 6. The resist 40 is previously patterned to have the same shape as the shape of the gate electrode 6 illustrated in FIG. 1 (a). That is, as illustrated in FIG. 3 (a), in the resist 40, a side of the right side thereof is parallel to the gate width direction and a side of the left side thereof has the convex portions 40a that extend along the gate length direction. In detail, the shape of the resist 40 becomes a shape of a comb that has comb teeth at one side.

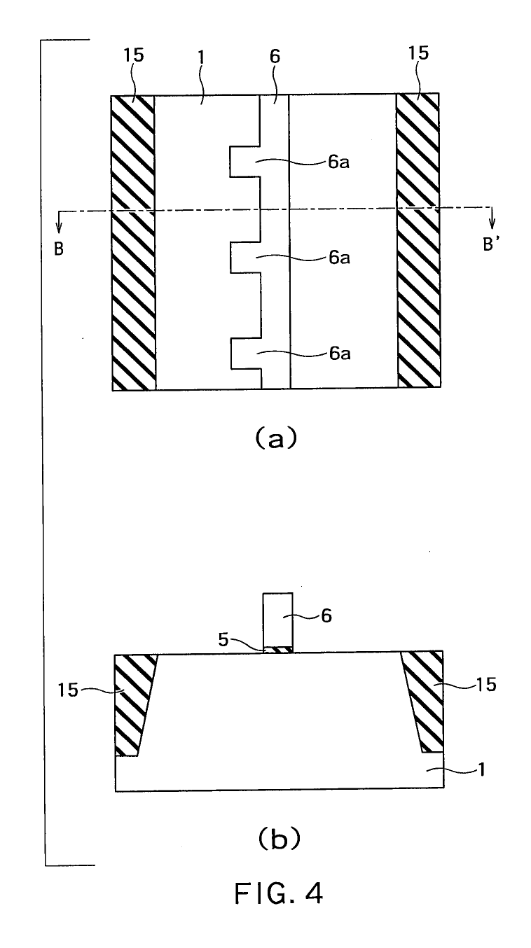

As illustrated in FIGS. 4 (a) and 4 (b), the gate insulating film 5 and the gate electrode 6 are processed using the patterned resist 40 as a mask and using a reactive ion etching (RIE) method. In this way, in the gate insulating film 5 and the gate electrode 6, the side of the right side is parallel to the gate width direction and the side of the left side has the convex portions 6a that extend along the gate length direction. In detail, the gate insulating film 5 and the gate electrode 6 have a shape of a comb that has comb teeth at one side.

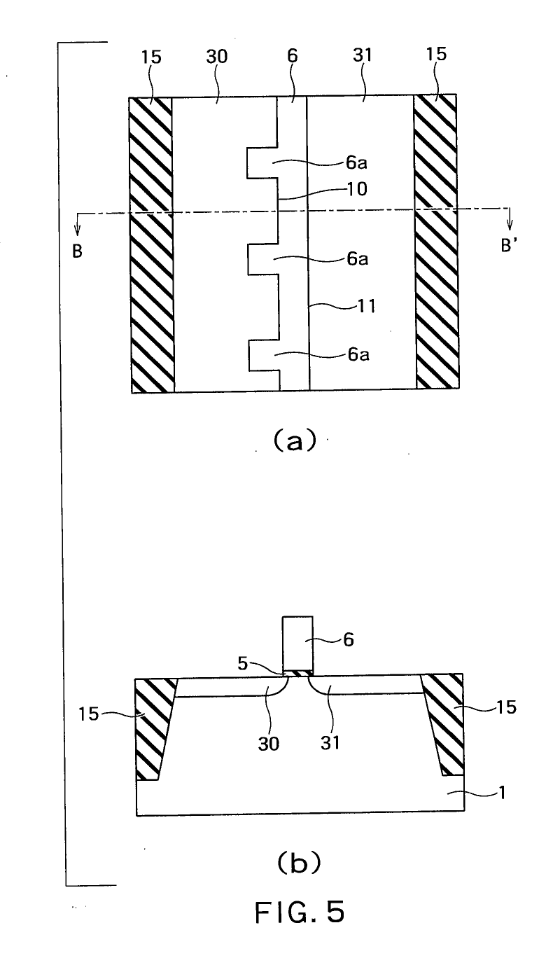

As illustrated in FIGS. 5 (a) and 5 (b), in this state, using the gate electrode 6 as the mask, the p-type impurities such as boron are implanted into the semiconductor substrate 1 of the left side of the channel region 4 and the n-type impurities such as phosphorous are implanted into the semiconductor substrate 1 of the right side of the channel region 4 and annealing is performed. In this way, the source extension region 30 and the drain extension region 31 are formed in the semiconductor substrate 1. In this way, as illustrated in FIG. 5 (a), if the semiconductor substrate 1 is viewed from a top surface thereof, the boundary of the source extension region 30 and the channel region 4 and the boundary of the drain extension region 31 and the channel region 4 have a shape that corresponds to the shape of the gate electrode 6. Therefore, the first boundary 10 that is the boundary of the source extension region 30 and the channel region 4 has an uneven shape, in detail, a rectangular wave shape. The second boundary 11 that is the boundary of the drain extension region 31 and the channel region 4 becomes a straight line that is parallel to the gate width direction.

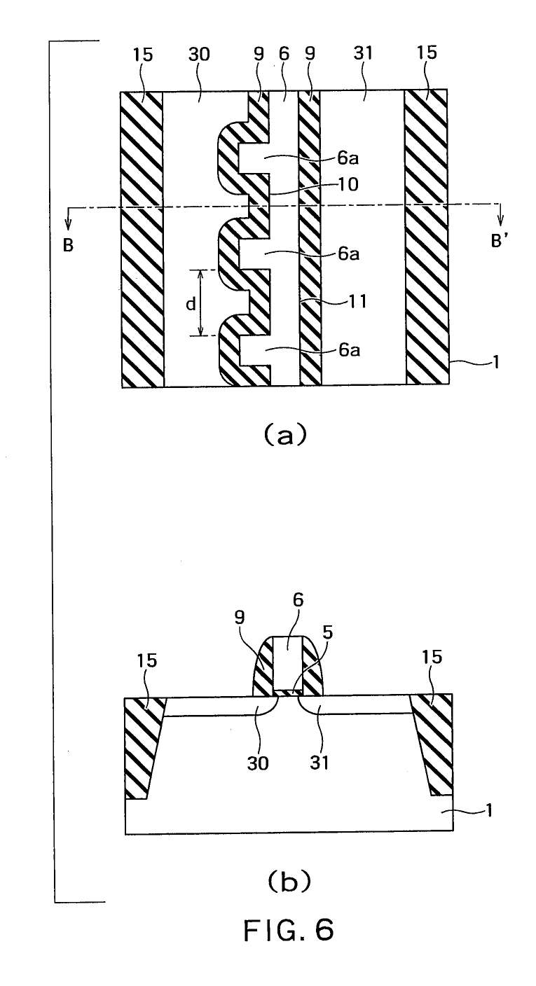

Next, in order to form the sidewall film 9, the silicon oxide film is deposited using the CVD method and anisotropic etching is performed with respect to the silicon oxide film using the RIE method. In this way, the sidewall film 9 illustrated in FIGS. 6 (a) and 6 (b) is formed. The shape of the sidewall film 9 can be appropriately selected according to the characteristic required with respect to the tunnel FET 21, as described above. When the sidewall film 9 is formed not to bury the regions between the adjacent convex portions 6a of the gate electrode 6, the gate electrode 6 is preferably formed such that the interval “d” of the adjacent convex portions 6a is two times more than the thickness of the sidewall film 9.

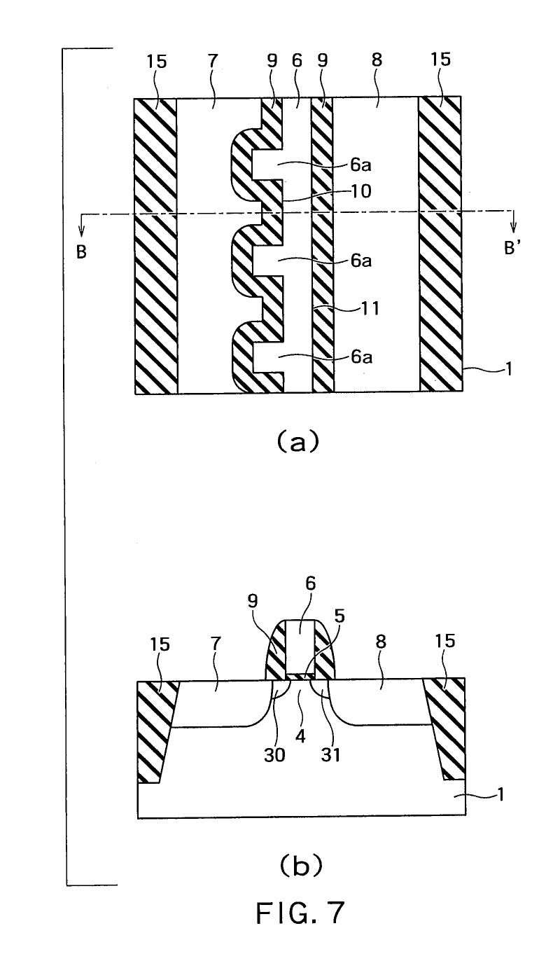

As illustrated in FIGS. 7 (a) and 7 (b), in this state, using the gate electrode 6 covered with the sidewall film 9 as the mask, the p-type impurities such as boron are implanted into the semiconductor substrate 1 of the left side of the channel region 4 and the n-type impurities such as phosphorous are implanted into the semiconductor substrate 1 of the right side of the channel region 4 and annealing is performed. In this way, the source region 7 and the drain region 8 are formed in the semiconductor substrate 1.

Then, the silicide film can be formed on the surfaces of the source region 7 and the drain region 8. The shape of the silicide film can be appropriately selected according to the characteristic required with respect to the tunnel FET 21, as described above.

According to this embodiment, the first boundary 10 that is the boundary of the source region 7 and the channel region 4 on the surface of the semiconductor substrate 1 is formed in the uneven shape, the length thereof is increased, and the places where the carriers perform tunneling increase. In addition, the drain current of the tunnel FET 21 can be increased. That is, the structure where the tunneling between the bands is performed in the transverse direction can be easily manufactured. However, the regions where the tunneling between the bands is generated are small as compared with the structure where the tunneling between the bands is performed in the longitudinal direction. For this reason, there is a problem in that the drain current is small. However, according to this embodiment, the problem can be resolved.

Since the conventional method of manufacturing the semiconductor device can be used, according to this embodiment, the tunnel FET can be easily formed. The gate electrode can be processed with high precision and the desired tunnel FET can be easily formed using the gate electrode processed with high precision as the mask.

In this embodiment, as illustrated in FIG. 1 (a), since the side of the gate electrode 6 at the side of the source region 7 has the convex portions 6a extending along the gate length direction, the gate length that is the distance of the source region 7 and the drain region 8 changes periodically along the gate width direction, in one tunnel FET 21. However, the change width of the gate length is small and an influence of a resistance value of the places where the carriers perform tunneling with respect to the characteristic of the tunnel FET 21 is large. For this reason, an influence of the change in the gate length with respect to the characteristic of the tunnel FET 21 decreases.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

1. A semiconductor device comprising:
a substrate;
a gate electrode provided on the substrate via a gate insulating film;
a channel region provided on the substrate below the gate electrode;
a source region provided on the substrate to be adjacent to one side of the channel region, the source region having first impurities and forming a first boundary with the channel region, the first boundary being tunnel channel for carriers; and
a drain region provided on the substrate to be adjacent to the other side of the channel region, the drain region having second impurities and forming a second boundary with the channel region,
wherein a side of the gate electrode at the side of the source region has a plurality of convex portions extending along a gate length direction,
a side of the gate electrode at the side of the drain region is parallel to a gate width direction,
the first boundary and the second boundary have shapes corresponding to the side of the gate electrode at the side of the source region and the side of the gate electrode at the side of the drain region, and
the length of the first boundary on a surface of the substrate is more than the length of the second boundary.

2. The semiconductor device of claim 1,
wherein the gate insulating film and the gate electrode have a shape of a comb that has comb teeth at the side of the source region.

3. The semiconductor device of claim 1,
wherein the channel width of the channel region at the side of the source region is more than the channel width of the channel region at the side of the drain region.

4. The semiconductor device of claim 1, further comprising:
a sidewall film covering the side of the gate electrode at the side of the source region and the side of the gate electrode at the side of the drain region.

5. The semiconductor device of claim 4,
wherein the sidewall film covering the side of the gate electrode at the side of the source region has a rectangular wave shape, a triangular wave shape, or a semicircular wave shape.

6. The semiconductor device of claim 5,
wherein the distance between the adjacent convex portions is two times more than the thickness of the sidewall film.

7. The semiconductor device of claim 4,
wherein the sidewall film covering the side of the gate electrode at the side of the source region has a shape of a comb that has comb teeth at the side of the drain region.

8. The semiconductor device of claim 1, further comprising:
a source extension region contacting an end of the gate electrode at the side of the source region; and
a drain extension region contacting an end of the gate electrode at the side of the drain region.

9. The semiconductor device of claim 1,
wherein surfaces of the source region and the drain region are covered with a silicide film.

10. A method of manufacturing a semiconductor device, the method comprising:
providing a channel region at the desired position on a substrate;
forming a gate electrode of which one side has convex portions extending along a gate length direction and the other side is parallel to a gate width direction on the channel region;
implanting first impurities into the substrate to be adjacent to one side of the gate electrode using the gate electrode as a mask to form a source region; and
implanting second impurities into the substrate to be adjacent to the other side of the gate electrode to form a drain region.

11. The method of claim 10,
wherein the gate insulating film and the gate electrode are formed to have a shape of a comb that has comb teeth at the side of one side.

12. The method of claim 10, further comprising:
forming a sidewall film to cover a side of the gate electrode at the side of the source region and a side of the gate electrode at the side of the drain region.

13. The method of claim 12,
wherein the sidewall film covering the side of the gate electrode at the side of the source region is formed to have a rectangular wave shape, a triangular wave shape, or a semicircular wave shape.

14. The method of claim 13,
wherein the distance between the adjacent convex portions is two times more than the thickness of the sidewall film.

15. The method of claim 10, further comprising:
forming a source extension region on the substrate to contact an end of the gate electrode at the side of the source region; and
forming a drain extension region on the substrate to contact an end of the gate electrode at the side of the drain region.

16. The method of claim 10, further comprising:
forming a silicide film to cover surfaces of the source region and the drain region.
